(19) United States
(12) Patent Application Publication
(10) Pub. No.: US 2013/0065334 A1
(43) Pub. Date: Mar. 14, 2013

(54) METHOD OF MANUFACTURING LASER DIODE DEVICE

(71) Applicant: Takashi MOTODA, Tokyo (JP)

(72) Inventor: Takashi MOTODA, Tokyo (JP)

(73) Assignee: MITSUBISHI ELECTRIC CORPORATION, Tokyo (JP)

(21) Appl. No.: 13/473,844

(22) Filed: May 17, 2012

(30) Foreign Application Priority Data
Sep. 8, 2011 (JP) 2011-196285

(51) Int. Cl. H01L 21/78

(52) U.S. Cl. 438/33; 257/E21.599

(57) ABSTRACT

A method of manufacturing a laser diode device includes: forming semiconductor layers on top of one another and supported by a top surface of a semiconductor substrate, the semiconductor layers including an active layer, forming a separation trench by etching and removing portions of the semiconductor layers, from a top semiconductor layer to and including the active layer; scribing a groove in a bottom surface of the semiconductor substrate, directly opposite and along the separation trench; and propagating a crack from the groove, splitting the semiconductor substrate along the groove and forming a cleaved surface extending from the bottom surface of the semiconductor substrate to a bottom surface of the separation trench.

### BACKGROUND OF THE INVENTION

1. Field of the Invention

The present invention relates to a method of manufacturing a laser diode device used, e.g., for industrial equipment, etc.

2. Background Art

Japanese Laid-Open Patent Publication No. H06-5703 discloses a technique for splitting a semiconductor substrate (or wafer) into individual laser diode device chips. In this technique, grooves are formed in the semiconductor substrate, and then the semiconductor substrate is split or cleaved along these grooves by causing crack propagation from the grooves. The splitting of the semiconductor substrate is such that the resulting laser diode devices have exposed cleaved surfaces.

Laser diode devices have an active layer. Therefore, if a semiconductor substrate having laser diode devices formed therein is cleaved by the technique disclosed in the above patent publication, the resulting cleaved surfaces include a cross-sectional surface of the active layer. It should be noted that the cleaved surfaces may have cracks or chippings, which may induce crystal defects in the active layer. This may degrade the performance of the laser diode devices.

### SUMMARY OF THE INVENTION

The present invention has been made to solve the foregoing problem. It is, therefore, an object of the present invention to provide a method of manufacturing a laser diode device whereby it is possible to split the semiconductor substrate without introducing crystal defects in the active layer. The features and advantages of the present invention may be summarized as follows.

According to one aspect of the present invention, a method of manufacturing a laser diode device includes the steps of forming a plurality of semiconductor layers on top of one another over a top surface of a semiconductor substrate, the plurality of semiconductor layers including an active layer, forming a separation trench by etching away portions of the plurality of semiconductor layers from the top semiconductor layer at least down to and including the active layer, scribing a groove in a bottom surface of the semiconductor substrate directly below and along the separation trench, and by causing crack propagation from the scribed groove, splitting the semiconductor substrate along the scribed groove so as to form a cleaved surface extending from the bottom surface of the semiconductor substrate to a bottom surface of the separation trench.

Other and further objects, features and advantages of the invention will appear more fully from the following description.

### BRIEF DESCRIPTION OF THE DRAWINGS

FIG. 1 is a diagram showing the plurality of semiconductor layers formed over the semiconductor substrate;

FIG. 2 is a diagram showing the separation trenches after they have been formed;

FIG. 3 is a diagram showing the electrodes after they have been formed;

FIG. 4 is a diagram showing the grooves after they have been formed; and

FIG. 5 is a diagram showing the way in which the semiconductor substrate is cleaved.

### DETAILED DESCRIPTION OF THE PREFERRED EMBODIMENT

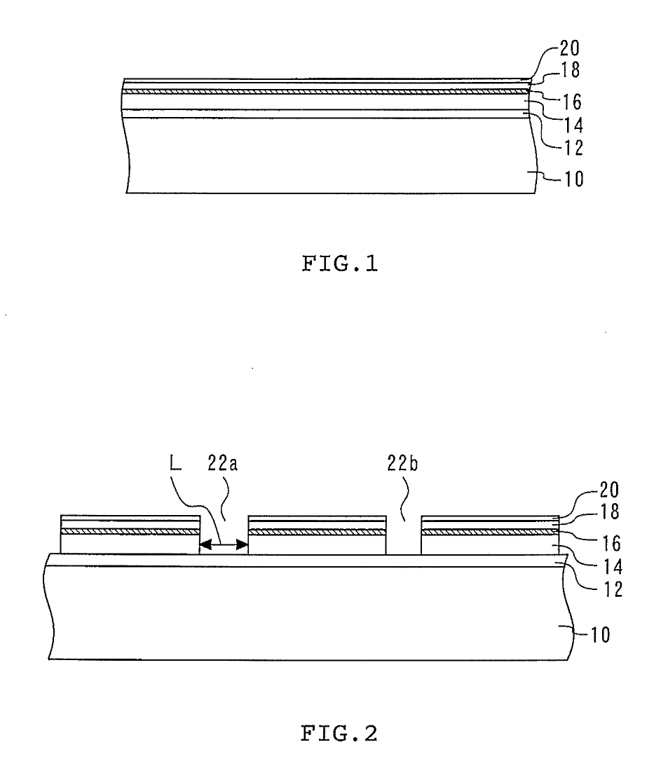

A method of manufacturing a laser diode device in accordance with an embodiment of the present invention will be described with reference to the accompanying drawings. First, a plurality of semiconductor layers including an active layer are formed over the surface of a semiconductor substrate. FIG. 1 is a diagram showing the plurality of semiconductor layers formed over the semiconductor substrate. Specifically, the semiconductor substrate 10 is formed of GaAs. A buffer layer 12 is formed on the semiconductor substrate 10. The buffer layer 12 is formed of a material having the same crystal structure and composition as the semiconductor substrate 10.

A lower cladding layer 14 is formed on the buffer layer 12. An active layer 16 is formed on the lower cladding layer 14. An upper cladding layer 18 is formed on the active layer 16. A contact layer 20 is formed on the upper cladding layer 18. Thus, the plurality of semiconductor layers including the active layer 16 are formed over the semiconductor substrate 10.

Next, separation trenches are formed. FIG. 2 is a diagram showing the separation trenches after they have been formed. Specifically in this step, portions of the plurality of semiconductor layers are etched away from the top semiconductor layer at least down to and including the active layer 16 so as to form separation trenches 22a and 22b. The separation trenches 22a and 22b shown FIG. 2 have been formed by etching the contact layer contact layer 20 and underlying layers down to the lower cladding layer 14. The surface of the buffer layer 12 is exposed at the bottom surfaces of the separation trenches 22a and 22b. The width (L) of the separation trenches 22a and 22b is 30 μm.

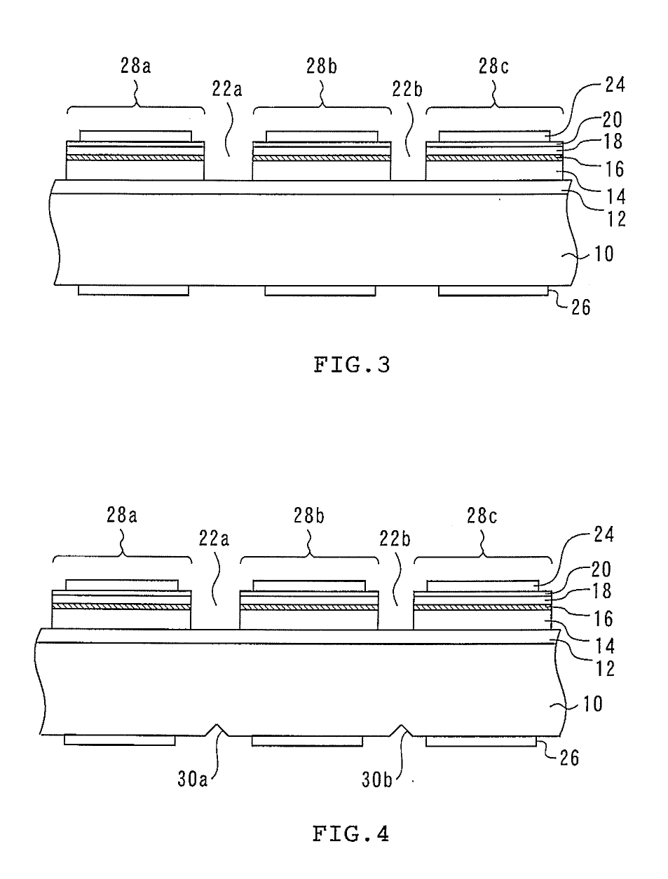

Electrodes are then formed. FIG. 3 is a diagram showing the electrodes after they have been formed. Specifically, an electrode 24 is formed on the contact layer 20, and an electrode 26 is formed on the bottom surface of the semiconductor substrate 10. This completes the formation of mesa stripes 28a, 28b, and 28c.

Next, grooves are scribed in the bottom surface of the semiconductor substrate. FIG. 4 is a diagram showing the grooves after they have been formed. Specifically, grooves 30a and 30b are formed in the bottom surface of the semiconductor substrate 10 directly below and along the separation trenches 22a and 22b, respectively. The grooves 30a and 30b are scribed by means of, e.g., a pen or scriber having a diamond tip.

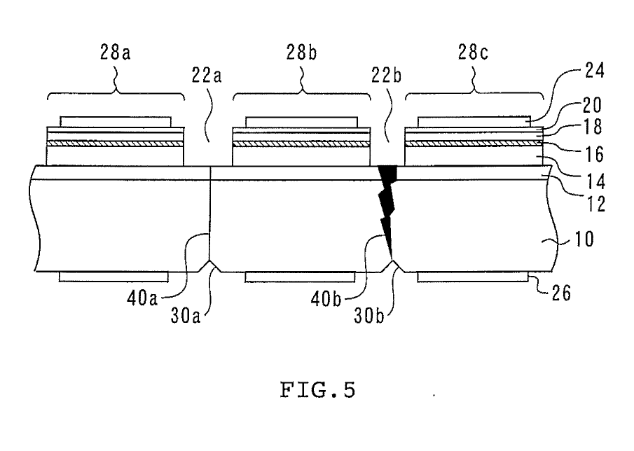

The semiconductor substrate 10 is then split or cleaved along the scribed grooves 30a and 30b by causing crack propagation from these grooves. FIG. 5 is a diagram showing the way in which the semiconductor substrate is cleaved. Specifically, the semiconductor substrate 10 is cleaved by causing crack propagation from the scribed grooves 30a and 30b, thereby forming cleaved surfaces extending from the bottom surface of the semiconductor substrate 10 to the bottom surfaces of the separation trenches 22a and 22b. If this cleavage operation is successful, the resulting cleaved surfaces are flat like the cleaved surface 40a shown in FIG. 5. It should be noted, however, that there is always some probability that a cleaved surface having cracks, like the cleaved surface 40b shown in FIG. 5, will appear.

In the laser diode device manufacturing method of the present embodiment, the separation trenches 22a and 22b are formed by etching away portions of the plurality of semiconductor layers from the top semiconductor layer at least down to and including the active layer 16. As a result, the cleaved surfaces produced when the semiconductor substrate is cleaved in the manner described above do not include a cross-sectional surface of the active layer 16. This means that even if the cleaved surfaces have cracks, that does not cause any crystal defect in the active layer 16. Further, the separation trenches 22a and 22b have a width of 30 μm which is large enough to prevent the cleavage cracks (or cleaved surfaces) from reaching the mesa stripes 28a, 28b, and 28c, which would otherwise cause crystal defects in the active layer 16. Further, since the scribed grooves 30a and 30b are provided in the bottom surface of the semiconductor substrate 10, there is no need to provide the separation trenches with scribed grooves, allowing arbitrary selection of the width (L) of the separation trenches 22a and 22b.

Various alterations may be made to the laser diode device manufacturing method of the present embodiment. The material of the semiconductor substrate 10 is not limited to GaAs, but may be any crystal having a zinc blende crystal structure, which has a tendency to cleave along the <110> direction. In the laser diode device manufacturing method of the present embodiment, the semiconductor substrate is split by utilizing this cleavage tendency. Therefore, the semiconductor substrate may be formed, e.g., of GaP.

The electrodes 24 and 26 may be formed before the separation trenches 22a and 22b are formed, or they may be formed after the grooves 30a and 30b are scribed. The material of the electrodes 24 and 26 may be, but is not limited to, gold, platinum, titanium, molybdenum, tantalum, nickel, or the like, or a multilayer film thereof. Further, the electrodes 24 and 26 may be plated with gold.

The requirement for the separation trenches 22a and 22b is only that they are formed by etching so as to extend through the active layer 16. Therefore, for example the separation trenches 22a and 22b may be formed to extend into the lower cladding layer 14 to the proximity of the bottom thereof.

Although the foregoing description of the laser diode device manufacturing method of the present embodiment does not describe the details of the structures of the plurality of semiconductor layers (epi layers), it is to be understood that the plurality of semiconductor layers can have any structure as long as one of them is an active layer. It should be noted that the active layer may be formed to have a QW, MQW, or SCH structure. The present invention may be applied to all types of laser diode devices having an active layer.

In accordance with the present invention, a semiconductor substrate having laser diode devices formed therein is cleaved in such a manner that the resulting cleaved surfaces do not include the active layer, making it possible to manufacture a laser diode device without introducing crystal defects in the active layer.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2011-196285, filed on Sep. 8, 2011, including specification, claims, drawings, and summary, on which the Convention priority of the present application is based, is incorporated herein by reference in its entirety.

1. A method of manufacturing a laser diode device comprising:
forming a plurality of semiconductor layers on top of one another and supported by a top surface of a semiconductor substrate, wherein said plurality of semiconductor layers includes an active layer;
forming a separation trench by etching and removing portions of said plurality of semiconductor layers, from a top semiconductor layer of said plurality of semiconductor layers, at least to and including said active layer;
scribing a groove in a bottom surface of said semiconductor substrate, directly opposite and along said separation trench; and
propagating a crack from said groove, splitting said semiconductor substrate along said groove, forming a cleaved surface extending from said bottom surface of said semiconductor substrate to a bottom surface of said separation trench.

2. The method according to claim 1, wherein said plurality of semiconductor layers further includes:
a buffer layer on said semiconductor substrate;
a lower cladding layer on said buffer layer;
an upper cladding layer on said active layer, wherein said active layer is on said lower cladding layer; and
a contact layer on said upper cladding layer.
